(19) United States
(12) Patent Application Publication
(10) Pub. No.: US 2024/0188270 A1
(43) Pub. Date: Jun. 6, 2024

(54) FEEDER AND COMPONENT MOUNTER

(71) Applicant: FUJI CORPORATION, Chiryu (JP)

(72) Inventors: Keita TANAKA, Takahama-shi (JP); Norio HOSOI, Chiryu-shi (JP)

(73) Assignee: FUJI CORPORATION, Chiryu (JP)

(21) Appl. No.: 18/554,008

(22) PCT Filed: Apr. 13, 2021
(86) PCT No.: PCT/JP2021/015306

§ 371 Date: Oct. 5, 2023

(51) Int. Cl. H05K 13/04

(52) U.S. Cl. CPC H05K 13/0419

(57) ABSTRACT

A feeder of the present disclosure includes a feeder main body configured to feed a tape in which a component is accommodated to a predetermined position; and a reel holder attached to an upstream side of the feeder main body in a feeding direction of the tape and configured to hold a reel on which the tape is wound. The reel holder is swingably attached to the feeder main body in an axial direction of the reel.

### TECHNICAL FIELD

The present description discloses a feeder and a component mounter.

### BACKGROUND ART

A component mounter picks up components supplied from multiple feeders set on a feeder setting base with a suction nozzle provided on a head, and mounts the components on a board. The feeder setting base is disposed on a front side of the component mounter. A feeder includes a reel on which a tape in which components are accommodated is wound. The feeder feeds the tape at a predetermined pitch so that the component is picked up by the suction nozzle. A feeder in which a reel holder is attached to a feeder main body (a feeder with a reel holder) is known as such a feeder. For example, in Patent Literature 1, a reel holder including a guide rail expandable and contractible in an up-down direction and a holder main body attached to the guide rail is disclosed as the reel holder.

### PATENT LITERATURE

Patent Literature 1: JP-A-2013-229628

### BRIEF SUMMARY

### Technical Problem

However, when an attempt is made to set a new feeder with a reel holder on a feeder setting base in a state in which multiple feeders with reel holders are set on the feeder setting base, it may be necessary to push adjacent reel holders to be widened therebetween in an axial direction of a reel.

The present disclosure has been made to solve the problems described above, and it is a main object of the present disclosure to cause a reel holder in a feeder with a reel holder to be pushed and widened in an axial direction of a reel.

### Solution to Problem

A feeder of the present disclosure includes:
a feeder main body configured to feed a tape in which a component is accommodated to a predetermined position; and
a reel holder attached to an upstream side of the feeder main body in a feeding direction of the tape and configured to hold a reel on which the tape is wound,
in which the reel holder is swingably attached to the feeder main body in an axial direction of the reel.

The feeder is a feeder with a reel holder, and the reel holder is swingably attached to the feeder main body in the axial direction of the reel. Therefore, when an attempt is made to set a new feeder on a feeder setting base in a state in which multiple feeders are set side by side on the feeder setting base, it is possible to push the adjacent reel holders to be widened therebetween.

### BRIEF DESCRIPTION OF DRAWINGS

FIG. 1 is a schematic explanatory view of component mounter 20.

FIG. 2 is a perspective view illustrating a state in which feeder 40 is set on feeder setting base 60.

FIG. 3 is a side view schematically illustrating feeder 40 set on feeder setting base 60.

FIG. 4 is a perspective view of reel holder 80 when holder main body 81 is disposed at upper position P1.

FIG. 5 is a perspective view of reel holder 80 when holder main body 81 is disposed at lower position P2.

FIG. 6 is a cross-sectional view taken along line A-A in FIG. 4.

FIG. 7 is an explanatory view illustrating a state in which reel holder 80 swings.

FIG. 8 is a block diagram illustrating electrical connection of component mounter 20.

FIG. 9 is a perspective view illustrating a state in which holder main body 81 is alternately disposed at upper position P1 and lower position P2.

FIG. 10 is a B-view of FIG. 9 (a plan view illustrating a state in which feeder 40 is extracted).

FIG. 11 is a B-view of FIG. 9 (a plan view illustrating a state in which feeder 40 is inserted).

FIG. 12 is a cross-sectional view illustrating a state in which reel holder 80 swings.

FIG. 13 is a cross-sectional view illustrating a state in which reel holder 80 swings in another example.

### DESCRIPTION OF EMBODIMENTS

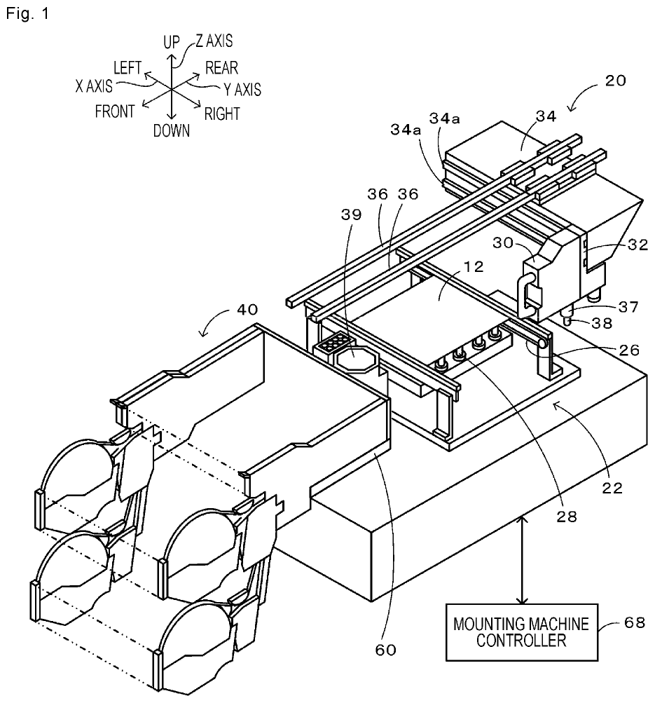

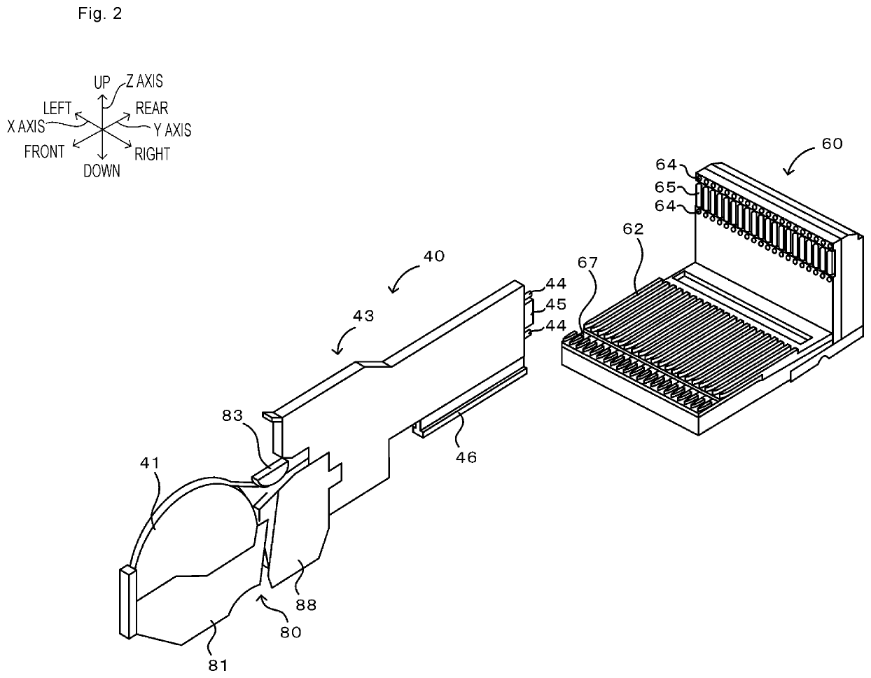

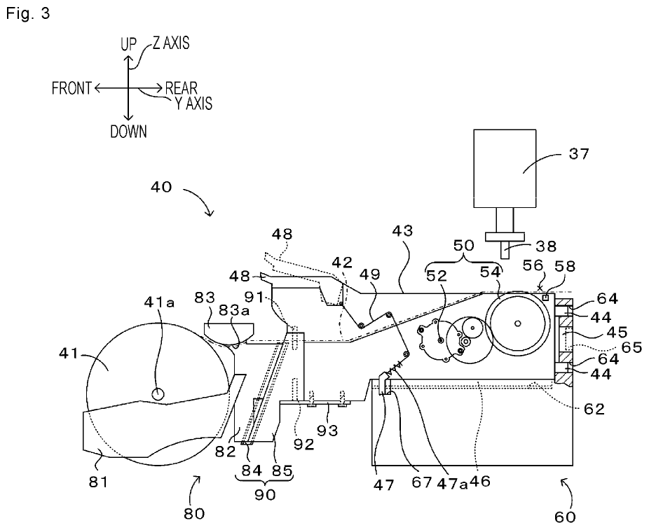

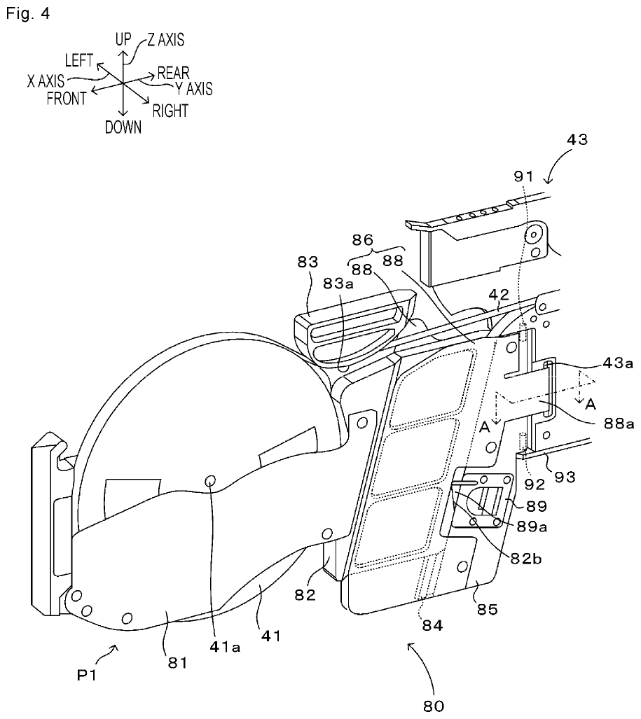

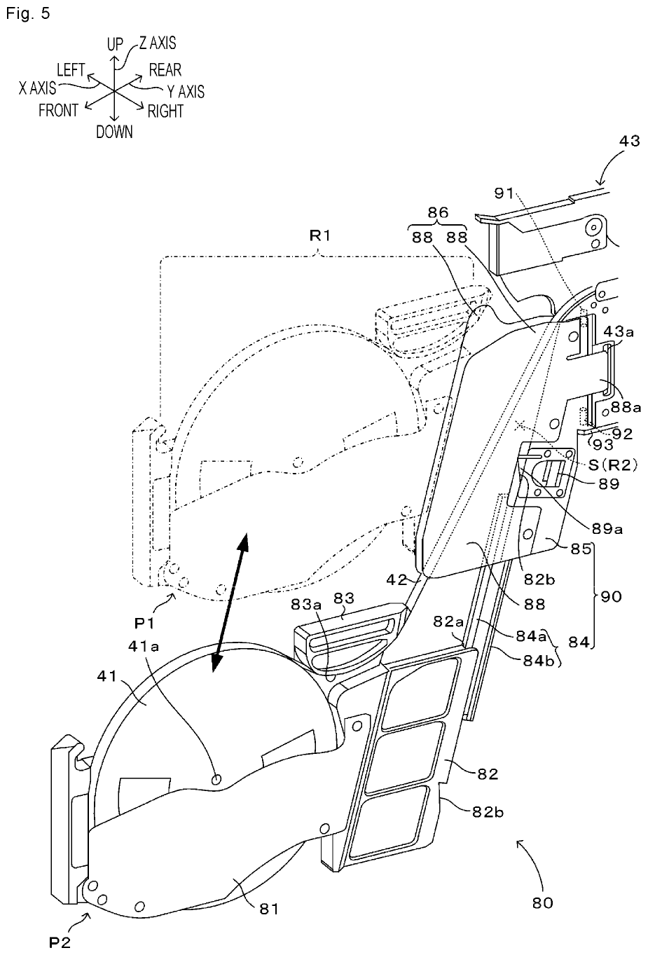

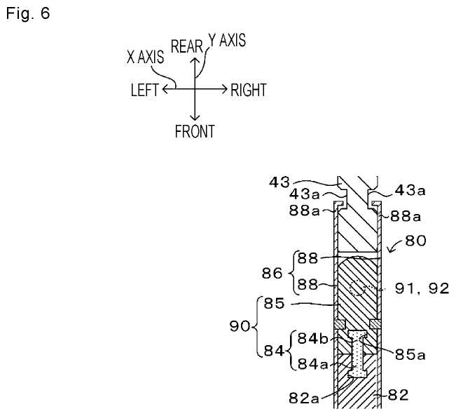

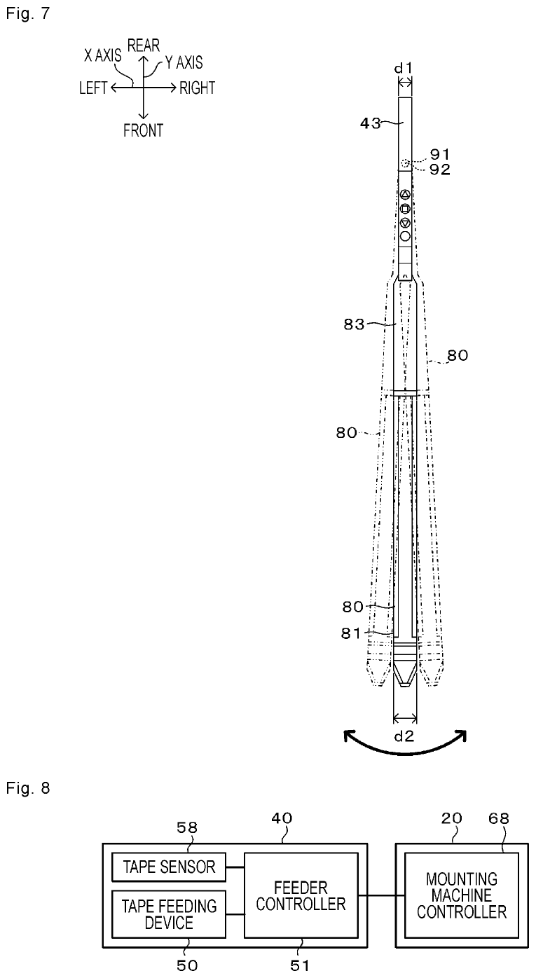

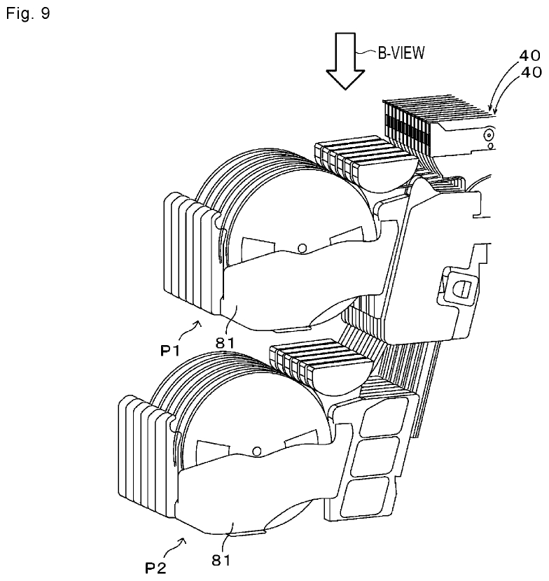

Preferred embodiments of the present disclosure will be described below with reference to the accompanying drawings. FIG. 1 is a schematic explanatory view of component mounter 20, FIG. 2 is a perspective view illustrating a state in which feeder 40 is set on feeder setting base 60, FIG. 3 is a side view schematically illustrating feeder 40 set on feeder setting base 60, FIG. 4 is a perspective view of reel holder 80 when holder main body 81 is disposed at upper position P1, FIG. 5 is a perspective view of reel holder 80 when holder main body 81 is disposed at lower position P2, FIG. 6 is a cross-sectional view taken along line A-A in FIG. 4, FIG. 7 is an explanatory view illustrating a state in which reel holder 80 swings, and FIG. 8 is a block diagram illustrating electrical connection of component mounter 20. In the present embodiment, a left-right direction (X axis), a front-rear direction (Y axis), and an up-down direction (Z axis) are as illustrated in the respective drawings.

Component mounter 20 includes board conveyance device 22, head unit 30, part camera 39, feeder 40, feeder setting base 60, and mounting machine controller 68.

Board conveyance device 22 includes a pair of conveyor belts 26 and 26 (only one is illustrated in FIG. 1) that are provided at intervals in the front-rear direction and extend in the left-right direction. Board 12 is placed on upper surfaces of the pair of conveyor belts 26 and 26 and is conveyed from the left to the right. In a case where board 12 reaches a predetermined loading position, board 12 is supported by a number of support pins 28 erected on a rear surface side.

Head unit 30 is detachably attached to a front surface of X-axis slider 32. X-axis slider 32 is slidably attached to a pair of upper and lower guide rails 34a and 34a extending in the left-right direction and provided on a front surface of Y-axis slider 34. Y-axis slider 34 is slidably attached to a pair of left and right guide rails 36 and 36 extending in the front-rear direction. Head unit 30 moves in the left-right direction as X-axis slider 32 moves in the left-right direction, and moves in the front-rear direction as Y-axis slider 34 moves in the front-rear direction. Each of sliders 32 and 34 is driven by a drive motor which is not illustrated. Head unit 30 has head 37 provided with nozzle 38. Nozzle 38 uses pressure to pick up components to a nozzle tip or to separate components picked up by the nozzle tip. A height of nozzle 38 can be adjusted by a Z-axis ball screw mechanism, which is not illustrated, mounted on head unit 30. Head 37 and nozzle 38 are suitably exchanged depending on the type and size of the components.

Part camera 39 is installed between feeder setting base 60 and board conveyance device 22 so that an imaging direction is directed upward at the approximate center of a length in the left-right direction. Part camera 39 images a component picked up by nozzle 38 passing thereabove and outputs an image obtained by the imaging to mounting machine controller 68.

As illustrated in FIG. 2 and FIG. 3, feeder 40 includes reel 41, reel holder 80, and feeder main body 43. Tape 42 having multiple accommodation recessed portions, which are not illustrated, is wound on reel 41 along a longitudinal direction. A component is accommodated in each accommodation recessed portion. These components are protected by a film, which is not illustrated, that covers a surface of tape 42.

Reel holder 80 is a member that holds reel 41 and is attached to an upstream side of feeder main body 43 in a feeding direction (a direction from the front to the rear) of tape 42. As illustrated in FIG. 7, reel holder 80 is swingably attached to feeder main body 43 in a direction of shaft 41a of reel 41 (a direction along shaft 41a of reel 41). Details of reel holder 80 will be described later.

Feeder main body 43 feeds tape 42 drawn out from reel 41 to predetermined component supply position 56. A pair of upper and lower positioning pins 44 and 44 are provided on a rear end surface of feeder main body 43, and connector 45 is provided between the pair of positioning pins 44 and 44. Rail 46 having an inverted T-shaped cross-sectional shape extending in the front-rear direction is provided on a lower surface of feeder main body 43. Clamp member 47 is provided on the lower surface of feeder main body 43 in front of rail 46. As illustrated in FIG. 3, clamp member 47 is urged by spring 47a to protrude downward from the lower surface. Clamp member 47 is connected to clamp lever 48 provided on a front upper surface of feeder main body 43 through wire 49. In a state in which clamp lever 48 is not operated, clamp lever 48 is at a clamping position (refer to a solid line in FIG. 3), and clamp member 47 protrudes from the lower surface. In a case where clamp lever 48 is pivoted to a clamp release position (refer to a dashed line in FIG. 3), clamp member 47 is pulled through wire 49 and is retracted from the lower surface. Tape feeding device 50 transmits the power of servo motor 52 to sprocket 54 through various gears, rotates sprocket 54, and feeds tape 42 engaged with sprocket 54 to the rear side. The film covering the component accommodated in the accommodation recessed portion of tape 42 is peeled off before reaching predetermined component supply position 56. Feeder main body 43 includes a tape sensor 58 in the vicinity of component supply position 56. Tape sensor 58 is a sensor that detects tape 42. Feeder main body 43 incorporates feeder controller 51 (refer to FIG. 8). Feeder controller 51 inputs a detection signal from tape sensor 58 and outputs a control signal to tape feeding device 50.

As illustrated in FIG. 2 and FIG. 3, feeder setting base 60 has multiple slots 62 on an upper surface thereof. Slot 62 is an inverted T-shaped cross-sectional groove extending in the front-rear direction, and is configured such that rail 46 of feeder 40 is inserted. Clamp groove 67 is provided in slot 62. Feeder setting base 60 has a standing wall at a rear end. On the standing wall, connector 65 is provided at a position corresponding to each slot 62, and positioning holes 64 and 64 are provided above and below connector 65. In a case where rail 46 of feeder 40 is inserted from the front side to the rear side of slot 62, clamp member 47 provided on the lower surface of feeder 40 is fitted into clamp groove 67. As a result, feeder 40 is supported in a vertically disposed state in slot 62, and a position in the front-rear direction is determined by clamp member 47 and clamp groove 67. In addition, positioning pins 44 and 44 of feeder 40 are fitted into positioning holes 64 and 64 of feeder setting base 60, and connector 45 of feeder 40 is electrically connected to connector 65 of feeder setting base 60. As a result, power supply is supplied from component mounter 20 to feeder 40. In addition, as illustrated in FIG. 8, feeder controller 51 is capable of bidirectional communication with mounting machine controller 68.

As illustrated in FIG. 3 to FIG. 5, reel holder 80 includes holder main body 81, slider 82, tape pressing member 83, movement mechanism 90, and duct 86. In FIG. 3, duct 86 is not illustrated.

Holder main body 81 is a member that rotatably holds reel 41. Reel 41 is rotatably held about shaft 41a. A direction of shaft 41a coincides with the left-right direction. Holder main body 81 is fixed to slider 82 by screws and is integrated with slider 82. As illustrated in FIG. 7, width d2 of holder main body 81 that holds reel 41 is larger than width d1 of feeder main body 43.

Slider 82 is a substantially rectangular member that moves holder main body 81 in the up-down direction. Long groove 82a in the up-down direction having a T-shaped cross-sectional shape is formed on a rear end surface of slider 82. In addition, recessed portion 82b is formed on the rear end surface of slider 82.

Tape pressing member 83 is a substantially semicircular plate member integrated with slider 82. Tape pressing member 83 has pressing section 83a having a substantially arcuate shape. Pressing section 83a presses tape 42 fed from reel 41 held by holder main body 81 toward feeder main body 43 from the upper side.

Movement mechanism 90 is a mechanism for supporting slider 82 integrated with holder main body 81 and tape pressing member 83 so as to be movable up and down between upper position P1 (a position indicated by chain lines) and lower position P2 (a position indicated by solid lines) as illustrated in FIG. 5. Holder main body 81 disposed at upper position P1 is referred to as upper holder main body 81, and holder main body 81 disposed at lower position P2 is referred to as lower holder main body 81. Movement mechanism 90 includes guide rail 84 and rail support 85.

Guide rail 84 is a linear rail extending in the up-down direction in a slightly inclined state, and supports slider 82 integrated with holder main body 81 and tape pressing member 83 so as to be movable up and down. As illustrated in FIG. 6, guide rail 84 has a H-shaped cross-sectional shape as a whole and includes front part 84a having a T-shaped cross-sectional shape and rear part 84b having a T-shaped cross-sectional shape. Front part 84a of guide rail 84 is fitted into long groove 82a of slider 82. As a result, slider 82 can slide in the up-down direction along guide rail 84.

Rail support 85 is a plate-shaped member having substantially the same thickness as slider 82, and is supported by feeder main body 43 so as to be immovable up and down. Rail groove 85a in the up-down direction having a T-shaped cross-sectional shape is formed on a front end surface of rail support 85. Rear part 84b of guide rail 84 is inserted into rail groove 85a. As a result, guide rail 84 is slidable in the up-down direction along rail groove 85a. In addition, rail support 85 includes lock member 89 as illustrated in FIG. 4 and FIG. 5. Lock member 89 includes claw section 89a having a shape corresponding to recessed portion 82b. Claw section 89a is urged by a spring, which is not illustrated, toward front slider 82.

As illustrated in FIG. 4 and FIG. 5, duct 86 includes a pair of metal thin plates 88 and 88 provided so as to sandwich rail support 85 from left and right, and is fixed to rail support 85 by screws. Therefore, duct 86 is held at the same height regardless of the movement of slider 82. Space S is formed between the pair of metal thin plates 88 and 88. Slider 82 disposed at upper position P1 is accommodated in space S. When slider 82 is disposed at lower position P2, space S becomes hollow.

Here, rail support 85 will be described in more detail. Rail support 85 is attached to be swingable in the left-right direction (in a direction of shaft 41a of reel 41) through upper and lower support shafts 91 and 92 of feeder main body 43. Upper support shaft 91 is screwed to feeder main body 43 and is inserted into an upper surface of rail support 85. Lower support shaft 92 is fixed to an upper surface of tongue-shaped bracket 93 screwed to the front of a lower surface of feeder main body 43, and is inserted into a lower surface of rail support 85. Plate spring section 88a having a substantially rectangular shape extending rearward is integrally formed on metal thin plate 88 fixed to rail support 85. A front end of plate spring section 88a is integrated with metal thin plate 88 and is fixed to rail support 85. A rear end of plate spring section 88a is in contact with feeder main body 43, but is not fixed. In the present embodiment, the rear end of plate spring section 88a is bent in an L shape and is hooked in long groove 43a in the up-down direction provided in feeder main body 43. Rail support 85 is an element of reel holder 80. Therefore, the configuration that rail support 85 is attached to feeder main body 43 in a swingable manner in the left-right direction results in that reel holder 80 is attached to feeder main body 43 in a swingable manner in the left-right direction.

Mounting machine controller 68 is configured as a microprocessor centered on CPU, and includes ROM for storing various programs, a storage for storing various data, RAM used as a work area, and the like. These are electrically connected through a bus which is not illustrated. In addition, mounting machine controller 68 is connected to board conveyance device 22, X-axis slider 32, Y-axis slider 34, a Z-axis ball screw mechanism, and the like so as to be able to output a control signal to those devices, and is also connected so that images can be input from part camera 39.

Next, an operation of component mounter 20 will be described. Mounting machine controller 68 of component mounter 20 controls board conveyance device 22, X-axis slider 32, Y-axis slider 34, the Z-axis ball screw mechanism, part camera 39, and the like based on the production job, and produces board 12 on which multiple components are mounted. Specifically, mounting machine controller 68 causes nozzle 38 to pick up components supplied by respective feeders 40, causes part camera 39 to image the components, performs correction based on the captured image, and then performs control such that the components picked up by nozzle 38 are mounted on board 12 in sequence.

Next, a case where an operator moves holder main body 81 of reel holder 80 between upper position P1 and lower position P2 will be described with reference to FIG. 5. In a case where holder main body 81 is moved from lower position P2 to upper position P1, the operator moves slider 82 integrated with holder main body 81 and tape pressing member 83 upward along guide rail 84 while moving guide rail 84 along rail groove 85a of rail support 85 and storing it in rail groove 85a. Then, claw section 89a of lock member 89 provided on rail support 85 engages with recessed portion 82b of slider 82 by the elastic force of the spring, and locks the movement of slider 82. As a result, holder main body 81 is disposed at upper position P1. On the other hand, in a case where holder main body 81 is moved from upper position P1 to lower position P2, the operator removes claw section 89a from recessed portion 82b by gripping lock member 89, moves slider 82 downward along guide rail 84, and extends guide rail 84 downward from rail groove 85a of rail support 85. As a result, holder main body 81 is disposed at lower position P2.

In this way, in a case where holder main body 81, slider 82, and tape pressing member 83 are disposed at lower position P2, tape pressing member 83 presses tape 42 such that tape 42 fed from reel 41 to feeder main body 43 does not pass through holder main body presence region R1, as illustrated in FIG. 5. Holder main body presence region R1 is a region in which holder main body 81 should be present if holder main body 81, slider 82, and tape pressing member 83 are disposed at upper position P1. In a case where holder main body 81, slider 82, and tape pressing member 83 are disposed at lower position P2, tape pressing member 83 presses tape 42 such that tape 42 fed from reel 41 to feeder main body 43 passes through empty space S (slider presence region R2) of duct 86. Slider presence region R2 is a region in which slider 82 should be present if holder main body 81, slider 82, and tape pressing member 83 are disposed at upper position P1.

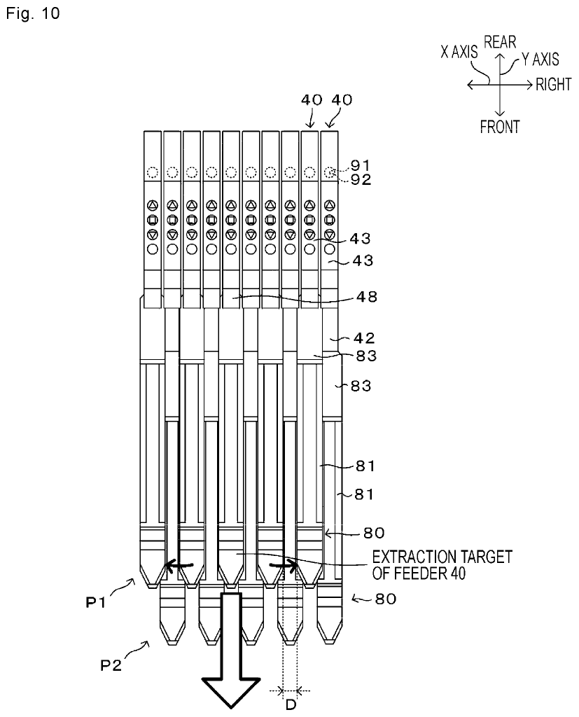

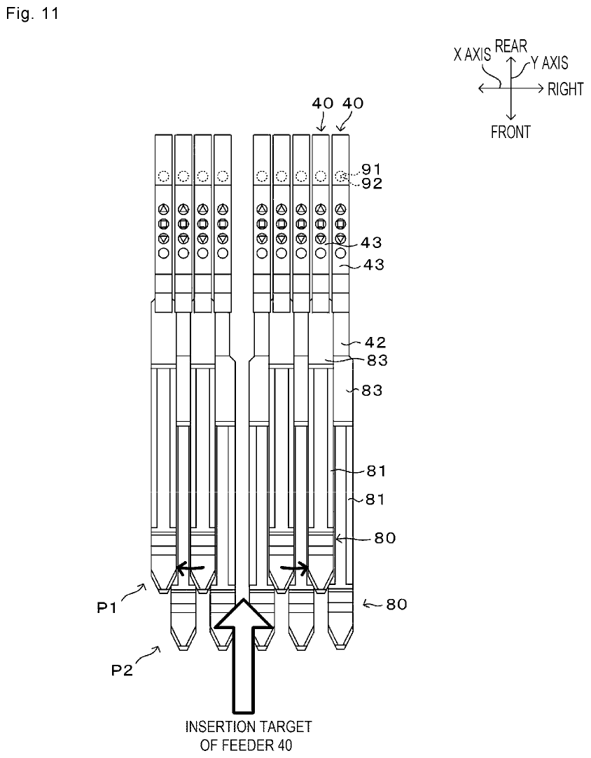

Next, an exchange operation performed when it is necessary to exchange one feeder 40 (referred to as extraction target of feeder 40) with another feeder 40 (referred to as insertion target of feeder 40) for any reason will be described. FIG. 9 is a perspective view illustrating a state in which holder main body 81 is alternately disposed at upper position P1 and lower position P2, FIG. 10 is a B-view of FIG. 9 (a plan view illustrating a state in which feeder 40 is extracted), and FIG. 11 is a B-view of FIG. 9 (a plan view illustrating a state in which feeder 40 is inserted). Here, it is assumed that feeder 40 is set in all slots 62 of feeder setting base 60. In addition, as illustrated in FIG. 9, it is assumed that feeder 40 in which holder main body 81 is disposed at upper position P1 and feeder 40 in which holder main body 81 is disposed at lower position P2 are alternately arranged in the left-right direction.

First, as illustrated in FIG. 10, the operator extracts extraction target of feeder 40 from slot 62. Specifically, the operator pivots clamp lever 48 of extraction target of feeder 40 to the clamp release position to release the clamp, and then pulls feeder 40 to the front side. As a result, slot 62 in which extraction target of feeder 40 is set becomes empty slot 62. In FIG. 10, extraction target of feeder 40 is exemplified by the one in which holder main body 81 is disposed at upper position P1.

Next, as illustrated in FIG. 11, the operator inserts and sets insertion target of feeder 40 into empty slot 62. Here, as insertion target of feeder 40, one in which the positions of drawing-out target of feeder 40 and holder main body 81 are the same (in FIG. 11, holder main body 81 is disposed at upper position P1) is prepared. The operator inserts insertion target of feeder 40 into empty slot 62 so as to pass between holder main bodies 81 disposed at upper positions P1 on both the left and right sides, and pivots clamp lever 48 to the clamping position to clamp feeder 40. As a result, the exchange operation is completed.

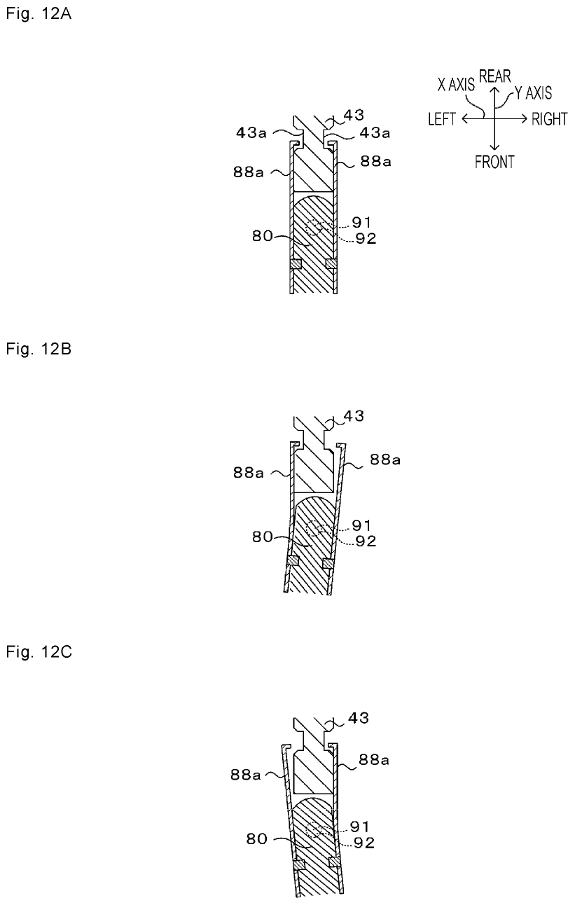

In a case where extraction target of feeder 40 is extracted from slot 62 or insertion target of feeder 40 is inserted into empty slot 62, the operator may push holder main body 81 disposed at upper position P1 in the vicinity of extraction target of feeder 40 or insertion target of feeder 40 in the left-right direction (refer to black arrows in FIG. 10 and FIG. 11). In a state in which external force is not applied to holder main body 81 disposed at upper position P1, reel holder 80 assumes a posture aligned in a straight line with feeder main body 43 in the front-rear direction by the action of plate spring sections 88a and 88a that sandwich feeder main body 43 from both sides, as illustrated in FIG. 12A. The position of reel holder 80 at this time is referred to as a basic position. In a case where holder main body 81 is pushed in a left direction, as illustrated in FIG. 12B, reel holder 80 including holder main body 81 swings in the left direction with respect to feeder main body 43 about upper and lower support shafts 91 and 92. At this time, a rear end of plate spring section 88a on the right side is separated from feeder main body 43, and plate spring section 88a on the left side is elastically deformed. In a case where the operator releases the hand from holder main body 81, feeder 40 returns to the basic position in FIG. 12A by the elastic force of plate spring section 88a. In a case where holder main body 81 is pushed in a right direction, as illustrated in FIG. 12C, reel holder 80 including holder main body 81 swings in the right direction with respect to feeder main body 43 about upper and lower support shafts 91 and 92. At this time, a rear end of plate spring section 88a on the left side is separated from feeder main body 43, and plate spring section 88a on the right side is elastically deformed. In a case where the operator releases the hand from holder main body 81, feeder 40 returns to the basic position in FIG. 12A by the elastic force of plate spring section 88a.

In feeder 40 described above, reel holder 80 is swingably attached to feeder main body 43 in the direction of shaft 41a of reel 41 (the left-right direction in the present embodiment). Therefore, when an attempt is made to set insertion target of feeder 40 in feeder setting base 60 in a state in which multiple feeders 40 are set side by side on feeder setting base 60 as described above, it is possible to push the adjacent reel holders to be widened therebetween. In addition, even if adjacent reel holders 80 are excessively pushed in the left-right direction, reel holders 80 swing in the left-right direction with respect to feeder main body 43. Therefore, it is possible to prevent reel holder 80 and feeder main body 43 from being damaged.

In addition, since reel holder 80 is attached to feeder main body 43 through upper and lower support shafts 91 and 92 provided along feeder main body 43 (in the up-down direction in the present embodiment), reel holder 80 can swing about upper and lower support shafts 91 and 92.

Further, reel holder 80 is attached to feeder main body 43 through plate spring sections 88a on both the left and right sides. Therefore, reel holder 80 is supported in the basic position (refer to FIG. 12A) by plate spring sections 88a on both sides in a state in which external force is not applied. In addition, in reel holder 80, in a case where an external force is applied in the left-right direction, plate spring section 88a elastically deforms and swings in the left-right direction, and in a case where the external force is removed, reel holder 80 returns to the original basic position by the elasticity of plate spring section 88a.

Furthermore, since reel holder 80 is attached through upper and lower support shafts 91 and 92, it is constantly supported by plate spring section 88a at the same basic position. In the basic position, since feeder main body 43 and reel holder 80 are in a posture aligned in a straight line in the front-rear direction, the operator can easily work with respect to reel holder 80.

The front ends of plate spring sections 88a and 88a on both the left and right sides are fixed to rail support 85 of reel holder 80 by screws, and the rear ends of plate spring sections 88a and 88a are not fixed to feeder main body 43. Therefore, when one of left and right reel holders 80 is pressed to feeder main body 43, a corresponding one of plate spring sections 88a is elastically deformed while remaining in contact with feeder main body 43, and another plate spring section 88a is separated from feeder main body 43. As a result, since plate spring section 88a is more likely to be elastically deformed even by a small external force, it is less likely to be damaged. In the present embodiment, although the rear ends of plate spring sections 88a and 88a are not fixed to feeder main body 43, it is preferable that reel holder 80 can be supported by feeder main body 43.

In addition, tape pressing member 83 suppresses reel 41 from being pulled upward by tape 42. Therefore, it is possible to prevent reel 41 from floating. In addition, in a case where holder main body 81 is disposed at lower position P2, tape 42 is pressed so that tape 42 fed from reel 41 to feeder main body 43 does not pass through holder main body presence region R1 (so as to pass through space S of duct 86). Therefore, in a case where multiple feeders 40 are set side by side on feeder setting base 60 in a predetermined direction and holder main body 81 is alternately disposed at upper position P1 and lower position P2, tape 42 directed from reel 41 held by holder main body 81 disposed at lower position P2 to feeder main body 43 does not pass between holder main bodies 81 disposed at upper position P1. Therefore, it is unnecessary to set interval D between holder main bodies 81 on the upper side (refer to FIG. 10) to be larger than a width of tape 42, and more feeders 40 can be set on feeder setting base 60 than in the conventional art. In addition, the efficiency in exchanging feeder 40 is also improved. Further, since tape 42 directed from reel 41 held by holder main body 81 on the lower side toward feeder main body 43 is protected by duct 86, tape 42 is prevented from lateral deviation.

The present disclosure is not limited in any way to the embodiments described above, and it is needless to say that the present disclosure can be implemented in various forms as long as they belong to the technical scope of the present disclosure.

In the embodiment described above, plate spring sections 88a are provided on the metal thin plates 88 on both the left and right sides, but plate spring section 88a may be provided on only one of the left and right metal thin plates 88.

In the embodiment described above, metal thin plate 88 is integrated with plate spring section 88a, but metal thin plate 88 and plate spring section 88a may be separate members. In this case, another elastic body may be used in place of the plate spring.

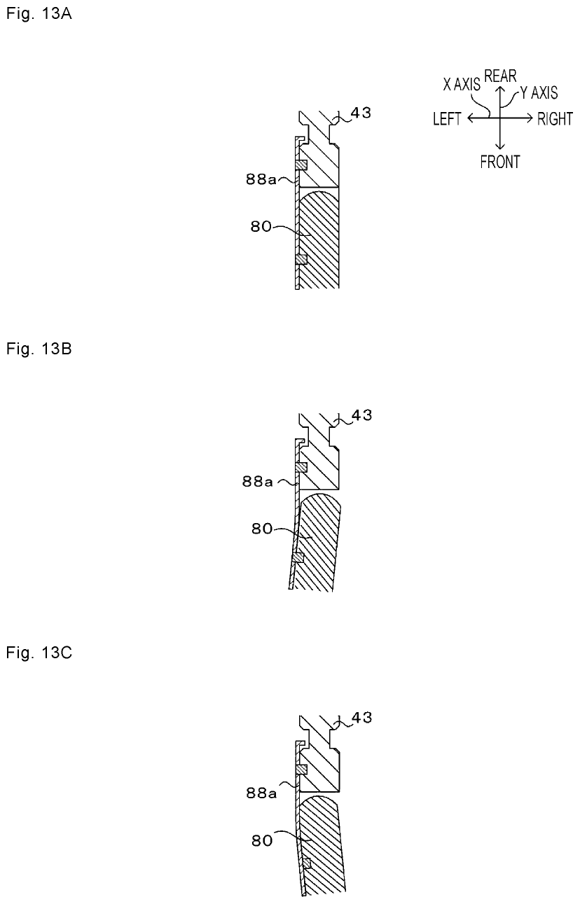

Reel holder 80 is attached to feeder main body 43 through upper and lower support shafts 91 and 92, and feeder main body 43 is sandwiched by the pair of plate spring sections 88a attached to reel holder 80 in the embodiment described above, but upper and lower support shafts 91 and 92 may be omitted. In this case, reel holder 80 may be supported by feeder main body 43 by causing the rear ends of the pair of plate spring sections 88a to enter long grooves 43a of feeder main body 43. In addition, in a case where upper and lower support shafts 91 and 92 are omitted, as illustrated in FIG. 13A, plate spring section 88a may be provided on one of the left and right sides (on the left side in FIG. 13), the front end of plate spring section 88a may be fixed to the side surface of reel holder 80, and the rear end of plate spring section 88a may be fixed to the side surface of feeder main body 43. By doing so, even with one plate spring section 88a, as illustrated in FIG. 13B and FIG. 13C, reel holder 80 can be permitted to swing in the left-right direction with respect to feeder main body 43, and reel holder 80 can be maintained in the basic position in FIG. 13A unless the external force is applied to reel holder 80. In a case where upper and lower support shafts 91 and 92 are omitted, plate spring sections 88a may be provided on both the left and right sides, but in such a case, reel holder 80 may become too rigid and may not swing easily in some cases. In such a case, it is preferable to provide plate spring section 88a on either the left or the right as illustrated in FIG. 13.

The front end of plate spring section 88a is fixed to reel holder 80, and the rear end of plate spring section 88a is not fixed to feeder main body 43 in the embodiment described above, but the rear end of plate spring section 88a may be fixed to feeder main body 43. However, in such a case, reel holder 80 may become too rigid and may not swing easily. In such a case, it is preferable that the rear end of plate spring section 88a is not fixed to feeder main body 43 as in the embodiment described above.

In the embodiment described above, a part of metal thin plate 88 is used as plate spring section 88a, but plate spring section 88a may be omitted. Even in this case, since reel holder 80 is swingably supported by feeder main body 43 through upper and lower support shafts 91 and 92, it is possible to obtain an effect that there is no possibility that reel holder 80 and feeder main body 43 are damaged even if holder main body 81 is pushed left and right.

In the embodiment described above, a configuration in which holder main body 81 is movable between upper position P1 and lower position P2 by using slider 82 is adopted, but a configuration in which holder main body 81 is fixed at upper position P1 may be adopted.

In the embodiment described above, tape pressing member 83 is adopted, but tape pressing member 83 need not be adopted.

In the embodiment described above, the nozzle is exemplified as a pickup member, but the pickup member is not particularly limited to the nozzle as long as the member can pick up the component. For example, a mechanical chuck or a robot hand that sandwiches and holds a component with a claw may be adopted in place of the nozzle.

### INDUSTRIAL APPLICABILITY

The present disclosure can be applied to various industries in which an operation of mounting components supplied from a feeder on a board is performed.

### REFERENCE SIGNS LIST

12: board, 20: component mounter, 22: board conveyance device, 26: conveyor belt, 28: support pin, 30: head unit, 32: X-axis slider, 34: Y-axis slider, 34a: guide rail, 36: guide rail, 37: head, 38: nozzle, 39: part camera, 40: feeder, 41: reel, 41a: shaft, 42: tape, 43: feeder main body, 43a: long groove, 44: positioning pin, 45: connector, 46: rail, 47: clamp member, 47a: spring, 48: clamp lever, 49: wire, 50: tape feeding device, 51 feeder controller, 52: servo motor, 54: sprocket, 56: component supply position, 58: tape sensor, 60: feeder setting base, 62: slot, 64: positioning hole, 65: connector, 67: clamp groove, 68: mounting machine controller, 80: reel holder, 81: holder main body, 82: slider, 82a: long groove, 82b: recessed portion, 83: tape pressing member, 83a: pressing section, 84: guide rail, 84a: front part, 84b: rear part, 85: rail support, 85a: rail groove, 86: duct, 88: metal thin plate, 88a: plate spring section, 89: lock member, 89a: claw section, 90: movement mechanism, 91: upper support shaft, 92: lower support shaft, 93: bracket, P1: upper position, P2: lower position, R1: holder main body presence region, R2: slider presence region, S: space

1. A feeder comprising:
a feeder main body configured to feed a tape in which a component is accommodated to a predetermined position; and
a reel holder attached to an upstream side of the feeder main body in a feeding direction of the tape and configured to hold a reel on which the tape is wound,
wherein the reel holder is swingably attached to the feeder main body in an axial direction of the reel.

2. The feeder according to claim 1,
wherein the reel holder is swingably attached to the feeder main body through a support shaft that is provided along the feeder main body.

3. The feeder according to claim 1,
wherein the reel holder is attached to the feeder main body through an elastic body, and is supported.

4. The feeder according to claim 3,
wherein the elastic body is a plate spring, is attached to a first surface of the reel holder, and
has a first end fixed to the reel holder and a second end fixed to the feeder main body.

5. The feeder according to claim 1,
wherein the reel holder is attached to the feeder main body through support shafts in an up-down direction, and has a plate spring that sandwiches the feeder main body from both sides of the reel holder.

6. The feeder according to claim 5,
wherein a first end of the plate spring is fixed to the reel holder and a second end is not fixed to the feeder main body.

7. A component mounter for picking up components supplied from multiple feeders set on a feeder setting base with a pickup member and mounting the components on a board,
wherein the feeders are the feeders according to claim 1.
